(19) United States
(12) Patent Application Publication
(10) Pub. No.: US 2006/0252254 A1
(43) Pub. Date: Nov. 9, 2006

(54) Filling deep and wide openings with defect-free conductor

(76) Inventor: Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/351,838

(22) Filed: Feb. 9, 2006

Related U.S. Application Data
(60) Provisional application No. 60/678,303, filed on May 6, 2005.

(51) Int. Cl. H01L 21/4763

(52) U.S. Cl. 438/628

(57) ABSTRACT

Relatively large openings or features in integrated circuit metallization or packaging vias are filled by two plating or electrodeposition processes in sequence. The first electrodeposition process conformally lines the large, high aspect ratio features to define an inner cavity. The second electrodeposition process uses a different solution to bottom-up fill the inner cavity left by the first electrodeposition process. Conformality is typically induced by use of levelers during the first electrodeposition, while accelerators and suppressors may be used to promote bottom-up fill during the second electrodeposition, although either process may employ any of the three additives.

### REFERENCE TO RELATED APPLICATIONS

The present application claims priority under 35 U.S.C. § 119(e) to U.S. provisional application No. 60/678,303, filed May 6, 2005.

### FIELD OF INVENTION

The invention generally relates to semiconductor integrated circuit technology and, more particularly, to electroplating processes.

### BACKGROUND

Conventional semiconductor devices or integrated circuits (ICs) generally include a semiconductor substrate, usually a silicon substrate, and a plurality of sequentially formed dielectric layers and conductive paths or interconnects made of conductive materials. IC interconnects are usually formed by filling a conductive material such as copper into features or cavities formed in the dielectric layers. Such features include, but are not limited to, vias and trenches that are filled to define lines, pads and contacts. In an integrated circuit, multiple levels of interconnect networks laterally extend with respect to the substrate surface. Interconnects formed in different layers can be electrically connected using vias filled with contacts.

Recently, work has been carried out to develop high-density, low-capacitance vertical interconnect technologies for integrated circuit systems. These wafer level integration and packaging technologies are aimed at increasing IC system performance in terms of speed and reduced power consumption while reducing weight and volume. The vertical interconnects enable three dimensional (3-D) homogeneous integration of multiple layers of ICs as well as 3-D heterogeneous integration of multiple layers of ICs with various devices fabricated in different materials. Thus, 3-D integration includes integrating multiple ICs either at the chip or wafer level. The resulting multi-layer structures offer optimal short interconnect paths and large inter-layer signal bandwidth compared to the prior wire bonding technologies, which had demonstrated high inductance, low speed, low wiring density and high cross talk.

3-D vertical interconnect structures comprise larger features in terms of depths and widths, compared to the standard IC interconnect structures. Standard IC interconnect structures include sub-micron width vias and trenches at lower metal layers and may also have 50-100 microns (μm) wide lines and bond-pads, especially at the highest metal layers. Feature depth may range from 0.15-0.6 μm for lower metal levels and it may be in the range of 1-3 μm at the higher metal levels of typical IC interconnects. In other words, the aspect ratios (depth-to-width ratios) of small or narrow features in an IC interconnect may be higher than 1, but the aspect ratios of the larger features (e.g., wider than about 3 μm in the above example) are smaller than 1. In comparison, 3-D integration structures are deeper. They typically include vias with diameters or widths of 3-100 μm or even wider and aspect ratios (depth-to-width ratios) up to about 10. In this case, even the 3 μm wide vias have aspect ratios larger than 1.0, typically larger than 3.0. Therefore, processes applicable to filling the narrow features of IC interconnects with a metal do not necessarily apply to filling the wider and deeper, i.e., larger, features of 3-D interconnects.

The most popular processing approach for filling a conductor into IC interconnect structures is electrochemical deposition or electroplating. Electroplating techniques are relatively low cost and they have the capability of filling narrow features in a bottom-up fashion, as will be described below, so that voids and other defects do not form in the features. In an electroplating process, a conductive material, such as copper, is deposited to fill such features. Then, a material removal technique, such as chemical mechanical polishing, is employed to planarize and remove the excess metal or overburden from the top surface of the wafer, leaving conductive material only in the features.

Standard electroplating techniques utilize special electrolytes containing organic and inorganic additives that promote bottom-up fill of narrow features on the wafer surface. These electrolytes typically comprise copper sulfate, sulfuric acid, chloride, suppressors, accelerators and optionally levelers. Suppressors attach to the growing copper surface, increasing polarization (therefore reducing deposition current density if the voltage is kept constant). Accelerators reduce polarization of copper surfaces that have been exposed to suppressors. In bottom-up filling or super-filling, deposition of the plated material, such as copper, occurs at a high rate from the bottom of the feature towards the top of the feature, as indicated in FIG. 1. FIG. 1 shows an exemplary narrow feature 2 of an IC interconnect structure with an aspect ratio of larger than one. The narrow feature 2 in FIG. 1 may, for example, be 0.04-0.2 μm in width, and its depth may be at least two times its width. The narrow feature 2 includes a bottom region 3 and a neck region 4 and is lined with a barrier layer 5 and typically a seed or glue layer (not shown) on which deposition of the conductive material can be initiated. When copper is electroplated into the narrow feature 2 using the special electrolyte with the additives mentioned above, deposition takes place in a bottom-up fashion as indicated by dashed line profile 6 which exemplifies the copper surface profile after a short deposition period, such as 3-15 seconds, at a deposition current density of 2-10 mA/cm². As can be seen from the profile 6, copper growth at the neck region 4 is reduced compared to copper growth at the bottom region 3, i.e., copper growth rate from the bottom of the feature is much higher than the copper growth rate on the upper ends of the feature walls. As deposition continues, copper fills the whole feature (dashed line profile 7) without any defects, such as voids or seams.

It has been shown that to achieve good bottom-up fill of narrow features of IC interconnect structures, the copper plating electrolyte should contain Cl⁻ ions, suppressor and accelerator species. The accelerators help obtain bottom-up copper fill into the narrow features. The suppressors suppress growth of copper at the neck region so that the opening of the feature does not prematurely close and leave a void inside. Chlorine molecules are believed to increase the effectiveness of the suppressors in electroplating electrolytes. Some electrolytes also contain levelers to avoid copper bumps forming over the narrow features after they are completely filled with copper. Copper plating electrolytes and additives having the above mentioned characteristics are available from companies such as Rohm and Haas and Enthone.

Although application of current electroplating techniques and electrolytes to fill standard size vias and trenches of IC interconnect structures gives satisfactory results, this is not true when such techniques are directly applied to filling features for 3-D integration structures with large features typically having 3 to 100 μm width and 10 to 200 μm depth. This is because, while the challenges of filling high aspect ratio features (e.g., tendency for the opening to pinch shut and form voids) remain for these large features, traditional additives are not as able to differentiate between the top surface and internal via surfaces when the openings are wide, as explained below.

FIG. 2A illustrates an exemplary substrate 10 including a 3-D integration structure feature 12 to be filled. A conductive layer, such as a seed layer 14, covers the interior of the feature 12 and the surface of the substrate 10 to form a base upon which electroplating can be initiated. There may be additional layers, such as one or more glue layers, barrier layers, and nucleation layers under the seed layer 14, that are not shown in FIG. 2A. An even current density distribution on the seed layer 14 is not possible when deeply penetrating cavities are involved, such as feature 12 shown in FIG. 2A. When a potential is applied to the seed layer 14 in FIG. 2A, current density at the surface of the substrate 10 and around the entrance of the feature 12 can be different than at the interior of the feature 12 and, especially, at the lower end of the feature 12. In FIG. 2A, high current receiving areas are denoted with ‘A’ whereas lower current receiving areas are denoted with ‘B’. It should be noted that in terms of primary current distribution due to geometric factors, the situation would be similar for the narrow features of standard IC interconnects, i.e. the current density at the neck region 4 of the narrow feature 2 shown in FIG. 1 would be higher than the current density deeper in the feature 2. However, as discussed before and shown in FIG. 1, the presence of the suppressor and accelerator molecules change this situation. Since the feature 2 shown in FIG. 1 is narrow, additive species cannot diffuse in and out freely. The surface concentration of accelerators at the bottom 3 of the feature 2 is enhanced compared to the neck region 4 where the surface concentration of suppressors is higher; therefore, bottom-up growth is achieved.

However, when the same electrolyte containing suppressors and accelerators is used to fill the feature 12 of FIG. 2A, the same bottom-up filling mechanism does not take place. In the feature 12 shown in FIG. 2A, the geometric factors dictate the primary current distribution to be higher at region A compared to region B. Since the feature 12 is wide, additives can freely diffuse in and out of the feature and get adsorbed on the copper depositing on the internal surface of the cavity of feature 12 rather uniformly. In other words, the suppressor and accelerator surface concentrations around regions A and B are substantially the same. Bottom-up growth requires more accelerator surface concentration at the bottom of the feature and more suppressor surface concentrations at the top opening or neck region of the feature. For the case of a wide and deep feature 12, such as the one shown in FIG. 2A, these conditions are not achieved, unlike the case of the narrow feature 2 shown in FIG. 1 for which these conditions are satisfied.

Consequently, as exemplified in FIG. 2B, the difference in current densities between regions A and B cause differences in deposition rates during a subsequent deposition process to form a conductor layer 16 on the seed layer 14. As depicted by dotted lines in the conductor layer 16, material growth on the high current receiving areas A are higher than the low current receiving areas B. As the plating process progresses, faster growing material layer around the entrance of the feature 12 closes the entrance before completely filling the feature 12, thereby leaving an unfilled portion 18 inside the conductor layer 16 within the feature. The unfilled portion 18 is a void defect that increases the electrical resistance and reduces the reliability of the 3-D integration structure during operation.

From the foregoing, there is a need for new plating processes for defect-free filling of 3-D integration structures.

### SUMMARY

In accordance with one aspect of the invention, a method of electrochemically filling a conductive material in a feature formed in a surface of a workpiece is provided. The method includes providing a workpiece with the feature having a width of at least two microns and a depth of at least twice the width. The feature and the surface of the workpiece are lined with a seed layer. A first electrodeposition process of the conductive material forms a substantially conformal conductive layer on the seed layer. The conformal conductive layer partially fills the feature and extends over the surface of the workpiece. A second electrodeposition process fills a remainder of the feature completely with the conductive material in a bottom-up fashion.

In accordance with another aspect of the invention, a method of electrochemically filling a conductive material in a feature formed in a surface of the wafer is provided. The method includes electrodepositing the conductive material from a first solution onto the surface to partially fill the feature having an aspect ratio larger than 2 with a conformal conductor coating an interior of the feature so that an inner cavity is formed. The conductive material is electrodeposited from a second solution, different from the first solution, onto the conformal conductor film to completely fill the inner cavity in a bottom-up manner.

In accordance with another aspect of the invention, a method for electrochemically filling conductive material in a feature formed in a surface of a workpiece is provided. The method includes performing a first electrodeposition process to form a substantially conformal conductive layer that partially fills the feature. The feature has a depth at least twice its width. After the first electrodeposition process, the substantially conformal conductive layer defines an inner cavity in the feature, where the inner cavity has a width less than 1 micron. A second electrodeposition process, different from the first process, fills the inner cavity completely with conductive material.

### BRIEF DESCRIPTION OF THE DRAWINGS

These and other aspects of the invention will be readily appreciated in view of the detailed description below and the drawings, which are meant to illustrate and not to limit the invention, and in which:

FIG. 1 is a schematic, cross-sectional view of a lower level submicron sized feature (e.g., via) in an integrated circuit, showing bottom-up electrochemical deposition using specialized additives;

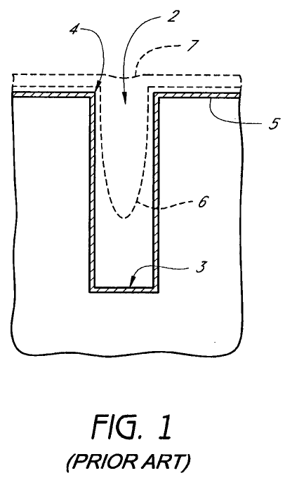

FIGS. 2A and 2B are schematic cross-sectional views of higher level integrated circuit metallization features or packaging vias with relatively wide openings and high aspect ratios, illustrating a lack of bottom-up filling behavior due to plating additives' inability to differentiate between top and inner surfaces of the structure; and

FIGS. 3 and 4 are sequential cross-sectional views of a wide and high aspect ratio feature for upper level integrated circuit or packaging interconnection, illustrating excellent fill capacity in accordance with preferred embodiments described herein.

### DETAILED DESCRIPTION

The preferred embodiments provide an electrochemical deposition process for reduced defects from filling of cavities having large width and depth, such as, for example, 3-D integration and packaging structures. Preferably, the process electrochemically fills a conductive material into such features having an aspect ratio of at least 2. The process may be performed in at least two steps, including: a first electrodeposition step that partially fills the cavity with a conductor and forms a conformal layer that reduces the width and the depth of the cavity; and a second electrodeposition step that completely fills conductor into the space defined by the conformal layer, preferably in a bottom-up fashion.

The first step may be performed using a first process solution having a chemistry that reduces growth at a neck region or opening of the feature and promotes conformal growth of the conductive material within the feature and forms a conformal layer in the feature without completely filling the feature. In contrast, the second step may be performed using a process solution having a second chemistry which promotes bottom-up filling of the narrower space left by the conformal deposition of the first step. In this example, the conductor that is deposited in both process steps may be copper or a copper alloy. However, it is possible to use another material in the first or the second steps of the process, thus yielding a heterogeneous structure consisting of copper and another material. An exemplary low resistivity material that can be used in the first or second step of the process is silver (Ag) or silver alloys or other conductive materials that may improve reliability of the 3-D interconnect structure.

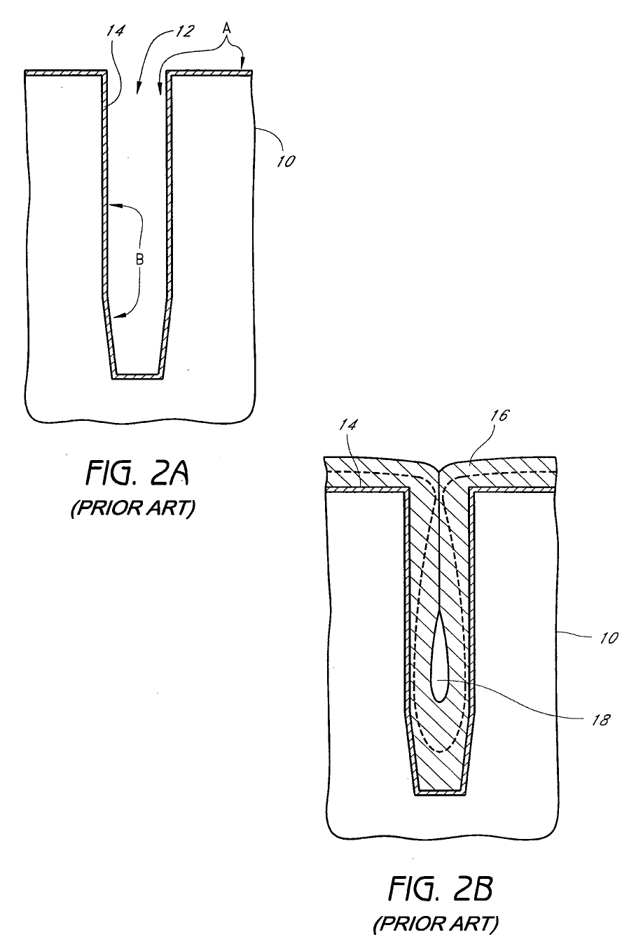

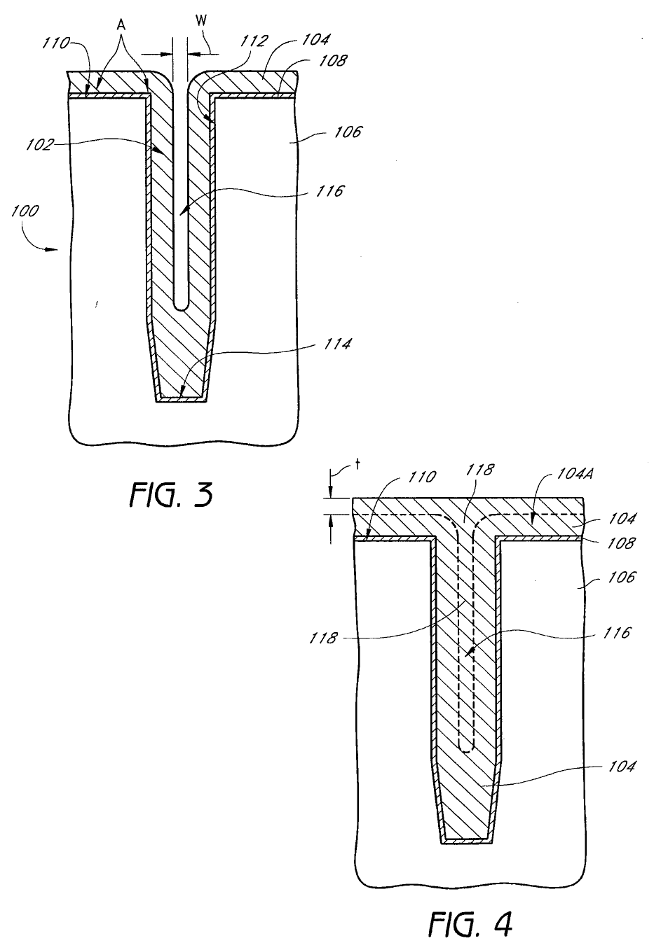

FIG. 3 shows a substrate 100 having an exemplary opening or feature 102, which is partially filled with a first layer 104, which is a substantially conformal layer, during a first step of the process according to an embodiment. The feature 102 is initially similar to the unfilled feature 12 shown in FIG. 2A. However, in FIG. 3, different reference numerals are used for purpose of clarity. Preferably, the feature has a width in the range of about 1-100 μm or even wider for 3-D integration, and typically 1-50 μm and more preferably in the range of 2-10 μm for upper level IC metallization. In either case, the width is typically greater than 2 μm and more preferably the width is greater than 5 μm. The depth of the vias is typically in the range of 3-10 μm for upper level IC metallization, and in the range of 20-200 μm for 3-D integration, typically greater than 25 μm and often greater than 50 μm. The aspect ratio is thus preferably greater than 2, and more preferably greater than 3. Such a via or feature 102, which is too wide and deep to effectively employ traditional bottom-up filling or conformal filling alone, is typical of the 3-D integration structures, but will also occur in some metallization processes, and particularly in packaging metallization.

The substrate 100 may be comprised of a dielectric layer 106 or a portion of a layer on a semiconductor wafer or workpiece (not shown). There may also be other structures (not shown) to which the feature 102 may be connected at its bottom portion. As shown in FIG. 3, in a first step of the process of this embodiment, the conformal layer 104 is preferably formed over a seed layer 108, coating the feature 102 and top surface 110 of the dielectric layer 106. As shown in FIG. 3, the seed layer 108 coats the internal side surface 112 and the bottom surface 114 of the feature 102. The seed layer 108 is typically formed on a barrier layer (not shown), such as a dielectric layer or a layer comprising a refractory material, such as Ta, TaN, Ti, TiN, etc. The seed layer 108 may be a thin layer of copper deposited using techniques such as atomic layer deposition (ALD), chemical vapor deposition (CVD), metal organic CVD (MOCVD) or physical vapor deposition (PVD).

The first layer 104 is preferably formed using an electrochemical deposition process (ECD). In this embodiment, the first layer 104 is formed by electrodepositing copper from a first deposition solution or electrolyte, which includes conformal (as opposed to bottom-up) layer forming agents or molecules, onto the seed layer 108. The “conformal” first has substantially the same thickness over the top surface 110 of the dielectric layer 106 as it does within the feature 102, as will be appreciated by the skilled artisan. The electrochemical deposition can be carried out by applying a potential difference between the seed layer 108 and an anode while wetting both the seed layer 108 and the anode with the electrolyte solution. The substrate 100 may be held by a holder (not shown) and may be moved during the process. In this embodiment, conformal layer forming agents may be levelers. Accordingly, an exemplary first solution composition may comprise copper sulfate, water, sulfuric acid, Cl⁻ ions, and levelers, in the absence of accelerators and suppressors. An exemplary leveler concentration may be 2-20 milliliters/liter (ml/l) of Enthone Viaform Leveler™. Alternatively, an alternative first solution composition may include accelerators and suppressors along with levelers. This exemplary alternative solution may have 0-4 ml/l accelerator concentration, 0-12 ml/l suppressor concentration and 2-20 ml/l leveler concentration for a high acid Enthone Viaform copper sulfate solution.

Leveler molecules in a solution have the property of being attracted to the regions on the substrate that receive high current. In that respect, in the prior art, addition of too much leveler in plating electrolytes has been avoided because bottom-up filling of narrow features entails high current density (therefore higher growth rate) at the bottom of the narrow feature; if too much leveler was in the electrolyte formulation, the leveler would be attracted to the high current density regions and disrupt the bottom-up fill mechanism. That is why, in the prior art, the leveler concentration in plating solutions have been carefully controlled. For example, in a high acid Enthone Viaform chemistry, the leveler concentration is kept typically in the range of 2-3 ml/l, and the leveler is used for the purpose of avoiding overfilling or bumping over the narrow features once the features are completely filled with copper. This prior art chemistry may also include 2-4 ml/l accelerator and 8-12 ml/l suppressor concentrations. The embodiment shown in FIG. 3, however, encourages the conformal deposition property of the levelers and advantageously uses this property to its benefit. Using the first deposition electrolyte with high leveler concentration, during the first step of the process, which is designed to avoid premature closing of the top opening of the feature 102, a defect free fill is preferably achieved as will be discussed below.

As stated above, leveler molecules in the first solution have the property of being attracted to the high current receiving areas, which for the illustrated wide and deep features are the areas A shown over the top surface 110 and around the upper end of the side surface 112, and suppress the fast material growth over such areas. Use of levelers enables the first layer 104 to grow in a substantially conformal manner with a substantially uniform thickness, thereby avoiding the problem of the prior art shown in FIG. 2B, where use of standard plating solutions cause premature closure of the entrance of the feature, leaving behind a void 18. The first layer 104 has a thickness preferably in the range of 0.5-25 μm, more preferably in the range of 1-10 μm, depending on the width of the feature 102. The current density during deposition is preferably in the range of 2-60 mA/cm² and it is selected based on its ability to yield the most conformal deposition within the feature 102 or reduced copper deposition at the neck region of the feature 102. Preferably, the first step of the deposition process continues until the first layer 104 partially fills the feature 102 by conformally coating the side surfaces 112 as well as the bottom surface 114 to form an inner cavity 116 with a width ‘W’. The predetermined width W of the inner cavity 116 is preferably less than 1 μm, and more preferably less than 0.6 μm, and the aspect ratio of the inner cavity 116 left after the first electrodeposition is preferably greater than 2:1, more preferably greater than 4:1. The predetermined width W preferably satisfies the conditions for bottom-up filling that will be performed in the second step.

As shown in FIG. 4, in the second electrodeposition step of the process, copper is deposited into the inner cavity 116 in a bottom-up fashion to form a second layer 118 that completely fills the inner cavity 116. The second step is preferably performed using an electrochemical deposition process utilizing a second solution or electrolyte that is different from the first solution, including deposition agents that promote bottom-up filling, such as accelerator and suppressor molecules. Alternatively, the second electrolyte may include accelerators, suppressors and a small amount of levelers. Leveler is used to avoid bumping of copper over the feature top opening after the feature is completely filled. An exemplary second solution, such as a commercially available high acid copper sulfate plating solution (Enthone Viaform^{TR}), may include 2-10 ml/l accelerator, 4-20 ml/l suppressor and 0-3 ml/l leveler concentrations.

In the following examples, alternative embodiments are provided. Deposition processes in the embodiments described below may be performed using electrochemical deposition process (ECD) or electrochemical mechanical deposition process (ECMD) using DC or pulsed power. Applied voltage or current to the workpiece may also be varied during the electrodeposition process. In an ECMD process, the surface of the substrate (top surface 110 shown in FIGS. 3 and 4) is swept by a pad, such as, for example, a fixed abrasive pad supplied by 3M Company or a polymeric pad such as an IC-1000 pad supplied by Rodel, while the electrolyte is delivered to the pad and a potential difference is applied between the surface 110 of the substrate and an anode. In an embodiment, the pad may be a polishing pad having openings or porosity allowing the flow of an electric field and the electrolyte. Exemplary ECMD apparatuses and processes are described in the following patents: U.S. Pat. No. 6,176,992, entitled “Method and Apparatus for Electro Chemical Mechanical Deposition;” U.S. Pat. No. 6,413,388, entitled “Pad Designs and Structures for a Versatile Materials Processing Apparatus;” and U.S. Pat. No. 6,534,116, entitled “Plating Method and Apparatus that Creates a Differential Between Additives Disposed on a Top Surface and a Cavity Surface of a Workpiece Using an External Influence.” The entire disclosures of all of the foregoing patents are hereby incorporated herein by reference for the purpose of explaining the ECMD planar plating process and equipment.

In a second embodiment, the first (conformal) deposition step of the process is performed as described above in connection with FIG. 3, using the first process solution to form the conformal first layer 104 and define the inner cavity 116. After the first deposition step, the surface of the first layer 104 is preferably treated or wetted with a third or treatment solution. The third solution composition preferably includes bottom-up filling promoting agents, such as accelerators. An exemplary third solution may have a 2-20 ml/l accelerator concentration. The third solution may be water or an acidic solution comprising known accelerator species, such as mercapto compounds or bis(sodiumsulfopropyl)disulfide, etc. After the treatment of the surface of the first layer 104, which preferably lasts about 2-60 seconds, the substrate 100 may be dried before the second deposition step. The treatment with the third solution prepares the surface of the first layer 104 for the second deposition step by allowing accelerators to be adsorbed on the surface of the first layer 104, especially on the surfaces within the cavities of the feature. Adsorbed accelerators further enhance the bottom-up filling of the inner cavity 116 without leaving behind defects, such as voids. Referring to FIG. 4, similar to the embodiment described above, in the second deposition step of this embodiment, the second layer 118 is formed in the inner cavity 116 using the second solution. Since the first layer 104 is already treated with accelerators, in this embodiment, the second solution may or may not include the accelerator molecules. In other words, the second solution for this embodiment may contain only suppressor molecules as additives, or both suppressor and accelerator molecules. It should be noted that for enhanced bottom-up growth, the steps of treatment and the second deposition step may be repeated one or more times. It should also be noted that known suppressor species are generally polyethylene glycol (PEG) related polymers with various molecular weights.

According to a third embodiment, the first (conformal) deposition step is performed as described above in connection with FIG. 3. After the first step, the second layer 118 is deposited, preferably using an ECMD process with the second solution in the second step. During the second step of this embodiment, a pad preferably sweeps a surface portion 104A (see FIG. 4) of the first layer 104, which is over the top surface 110 of the dielectric layer 106 while the copper deposits. Sweeping action on the first layer portion 104A reduces or inhibits growth of copper on the surface portion 104A while the copper deposits in the inner cavity 116 in a bottom-up fashion. Referring to FIG. 4, ECMD minimizes the thickness ‘t’ over the first layer on the surface portion 104A. It also enhances bottom-up fill of the inner cavity 116.

In a fourth embodiment, the first (conformal) deposition step is performed as described above in connection with FIG. 3. After the first deposition step, the surface of the first layer 104 is preferably treated or wetted with the third solution that is described above with respect to the second embodiment. The third solution composition preferably includes bottom-up filling promoting agents, such as accelerators. After the treatment of the surface of the first layer 104, the substrate 100 may be dried before the second deposition step. In the second deposition step, the second layer 118 is deposited, preferably using an ECMD process with the second solution. During the second step of this embodiment, a pad preferably sweeps the surface portion 104A (see FIG. 4) of the first layer 104. As mentioned above, sweeping action on the first layer portion 104A reduces or inhibits growth of copper on the surface portion 104A while the copper deposits in the inner cavity 116 in a bottom-up fashion. Referring to FIG. 4, ECMD minimizes the thickness ‘t’ over the first layer on the surface portion 104A. Since the first layer 104 is already treated with accelerators, in this embodiment, the second solution may or may not include the accelerator molecules. In other words, the second solution for this embodiment may contain only suppressor molecules as additives, or both suppressor and accelerator molecules. It should be noted that for enhanced bottom-up growth, the steps of treatment and second deposition step may be repeated one or more times.

In a fifth embodiment, the first (conformal) deposition step is performed as described above in connection with FIG. 3. After the first deposition step of this embodiment, the surface of the first layer 104 is preferably treated or wetted with the third solution, which is described above with respect to the second embodiment. The third solution composition preferably includes bottom-up filling promoting agents, such as accelerators. After the treatment, a pad preferably sweeps the surface portion 104A (see FIG. 4) of the first layer 104 to substantially remove accelerators from the surface portion 104A. During this pad sweeping step, the surface of the first layer 104 may also be rinsed with water. The substrate may be dried before the second deposition step. Referring to FIG. 4, in the second deposition step, the second layer 118 is deposited using either ECD or ECMD with the second electrolyte to fill the inner cavity 116 in a bottom-up fashion. As mentioned above, the second electrolyte may contain only suppressors, or both suppressors and accelerators since the surface of the first layer is treated with an accelerator containing solution. If this treatment step were not performed, then the second electrolyte would preferably contain accelerators and suppressors. In this embodiment, the sweeping of the surface of the first layer 104 before the second deposition step reduces accelerator surface concentration at the top surface that is swept. The accelerator concentration within the inner cavity 116 stays unaffected since these cavities are not swept by the pad. This surface concentration gradient of accelerator (inner cavity surfaces being richer in accelerator than the top surface) enhance the bottom-up fill of the inner cavity 116 and reduces copper growth rate on the top surface 104A, thereby reducing the upper surface thickness “t”.

Although various preferred embodiments and the best mode have been described in detail above, those skilled in the art will readily appreciate that many modifications of the exemplary embodiment are possible without materially departing from the novel teachings and advantages of this invention.

We claim:

1. A method of electrochemically filling a conductive material in a feature formed in a surface of a workpiece, comprising:
providing the workpiece with the feature having a width of at least 2 microns and a depth of at least twice the width, wherein the feature and the surface of the workpiece are lined with a seed layer;
performing a first electrodeposition process of the conductive material to form a substantially conformal conductive layer on the seed layer, the conformal conductive layer partially filling the feature and extending over the surface of the workpiece; and
performing a second electrodeposition process to fill a remainder of the feature completely with the conductive material in a bottom-up fashion.

2. The method of claim 1, wherein performing the first electrodeposition process includes an electrochemical deposition process using a first solution.

3. The method of claim 2, wherein the first solution includes a conformality-promoting species.

4. The method of claim 3, wherein the conformality-promoting species includes a leveler.

5. The method of claim 4, wherein the first solution comprises a leveler concentration of 2-20 ml/l.

6. The method of claim 2, wherein performing the second electrodeposition process includes an electrochemical deposition process using a second solution different from the first solution.

7. The method of claim 6, wherein the second solution includes a bottom-up filling promoting species.

8. The method of claim 7, wherein the bottom-up filling promoting species includes an accelerator.

9. The method of claim 8, wherein the second solution comprises an accelerator concentration of 2-10 ml/l.

10. The method of claim 1, further comprising treating a surface of the conformal conductive layer with a treatment solution prior to performing the second electrodeposition process, wherein the solution includes a bottom-up filling promoting species.

11. The method of claim 10, further comprising sweeping a surface portion of the conformal conductive layer after treating, wherein the surface portion is on the surface of the workpiece.

12. The method of claim 10, further comprising drying the conformal conductive layer after treating.

13. The method of claim 10, wherein the bottom-up filling promoting species includes an accelerator.

14. The method of claim 13, wherein the treatment solution comprises an accelerator concentration of 2-20 ml/l.

15. The method of claim 1, wherein performing the second electrodeposition process comprises electrochemical mechanical deposition.

16. The method of claim 1, wherein performing the first electrodeposition to form the substantially conformal conductive layer within the feature results in an inner cavity having a width.

17. The method of claim 16, wherein the width is less than 1 micron.

18. The method of claim 16, wherein the width is less than 0.6 micron.

19. The method of claim 1, wherein the feature has a depth greater than 50 μm.

20. A method of electrochemically filling a conductive material in a feature formed in a surface of wafer, comprising:
electrodepositing the conductive material from a first solution onto the surface to partially fill the feature having an aspect ratio larger than 2 with a conformal conductor coating an interior of the feature so that an inner cavity is formed; and
electrodepositing the conductive material from a second solution different from the first solution onto the conformal conductor to completely fill the inner cavity in a bottom-up manner.

21. The method of claim 20, wherein a width of the inner cavity is less than 1 micron.

22. The method of claim 20, wherein a width of the inner cavity is less than 0.6 micron.

23. The method of claim 20, wherein the first solution includes a conformality-promoting species.

24. The method of claim 23, wherein the conformality-promoting species includes a leveler.

25. The method of claim 24, wherein the first solution comprises a leveler concentration of 2-20 ml/l.

26. The method of claim 20, wherein the second solution includes a bottom-up filling promoting species.

27. The method of claim 26, wherein the bottom-up filling promoting species includes an accelerator.

28. The method of claim 27, wherein the second solution comprises an accelerator concentration of 2-10 ml/l.

29. A method for electrochemically filling conductive material in a feature formed in a surface of a workpiece, comprising:
performing a first electrodeposition process to form a substantially conformal conductive layer that partially fills the feature, wherein the feature has a depth at least twice its width, and wherein after the first electrodeposition process the substantially conformal conductive layer defining an inner cavity in the feature, the inner cavity having a width less than one micron; and
performing a second electrodeposition process different from the first process to fill the inner cavity completely with conductive material.

30. The method of claim 29, wherein the substantially conformal conductive layer has a thickness of about 1-10 microns.

31. The method of claim 29, wherein performing the first electrodeposition process includes an electrochemical deposition process using a first solution including a leveler.

32. The method of claim 31, wherein performing the second electrodeposition process uses a second solution different from the first solution.

33. The method of claim 32, wherein the second solution includes an accelerator.

34. The method of claim 29, wherein prior to performing the first electrodeposition process, the feature has an opening too wide for suppressors and accelerators to differentiate between interior surfaces of the feature and upper surfaces of the workpiece.

35. The method of claim 34, wherein prior to performing the first electrodeposition process, the feature has a width greater than 2 microns.

36. The method of claim 35, wherein prior to performing the first electrodeposition process, the feature has a width greater than 5 microns.

37. The method of claim 29, wherein the conductive material and the conformal conductive layer both comprise copper.
